(19) United States
(12) Patent Application Publication
(10) Pub. No.: US 2026/0004831 A1
(43) Pub. Date: Jan. 1, 2026

(54) DRIVER CIRCUITRY FOR HIGH-DENSITY MEMORY BANKS

(71) Applicant: Micron Technology, Inc., Boise, ID (US)

(72) Inventor: Venkataramana Gangasani, Meridian, ID (US)

(21) Appl. No.: 19/062,859

(22) Filed: Feb. 25, 2025

Related U.S. Application Data
(60) Provisional application No. 63/664,868, filed on Jun. 27, 2024.

(51) Int. Cl. G11C 8/08

(52) U.S. Cl. CPC G11C 8/08

(57) ABSTRACT

This disclosure is directed to column driver circuitry of a memory device. A memory bank of the memory device may include multiple memory cells arranged along multiple column select lines and row select lines. The column driver circuitry may include column drivers coupled to the column select lines. A column driver may generate a column select signal with multiple voltage steps for accessing a target memory cell coupled to a respective column select line. The column decoder may include circuitry to adjust a voltage level and/or duration of each voltage step of the column select signal to provide a desired voltage level to a target memory cell based on a disposition of the target memory cell along a column select line. For example, the column decoder may output a higher voltage level followed by a lower voltage level to access the target memory cell. The higher voltage level and the lower voltage level may be above a threshold voltage level for accessing the target memory cell.

### CROSS-REFERENCE TO RELATED APPLICATIONS

This application claims priority to U.S. Provisional Application No. 63/664,868, filed Jun. 27, 2024, which is incorporated by reference herein in its entirety.

### BACKGROUND

The present disclosure relates generally to memory devices. In particular, the present disclosure is related to column decoder circuitry and row decoder circuitry of the memory devices.

A memory device may include multiple memory banks. Each memory bank may include a number of memory cells arranged in a number of columns and rows. Each memory cell of a memory bank may be coupled to a column select line and a row select line of the memory bank. The memory device may receive a memory access request targeting one or more of the memory cells. In response to the memory access request, a column decoder of the memory device may output a column select signal to a column select line coupled to a target memory cell. Moreover, a row decoder of the memory device may output a row select signal to a row select line coupled to the target memory cell. The target memory cell may be accessed based on receiving the column select signal and the row select signal. The target memory cell may be accessed for writing data or reading stored data.

It is generally desired to increase storage capacity of memory banks and/or memory devices. A memory bank may include additional memory cells to have an increased storage capacity. For example, the additional memory cells may be arranged along the columns and rows of the memory cells thereby increasing a length of the column select lines and/or the row select lines. The column decoder may be coupled to one side of the columns. Moreover, a resistance and a parasitic capacitance for accessing a target memory cell is at least partly based on a length of a column select line coupling the column decoder to the target memory cell. As such, resistances and/or parasitic capacitances for accessing far memory cells of the memory bank may be increased based on the increased length of the respective column select lines. The far memory cells may be disposed at a far end of the column select lines near an opposite side of the memory bank with respect to the side coupled to the column decoder. If not compensated for, the increased resistances and/or parasitic capacitances may reduce a voltage and/or current of column select signals for accessing the far memory cells. Accordingly, it is desired to compensate for the increased resistances and/or parasitic capacitances associated with accessing the memory cells at a far end or near an opposite side of the column decoder and/or the row decoder.

### BRIEF DESCRIPTION OF THE DRAWINGS

Various aspects of this disclosure may be better understood upon reading the following detailed description and upon reference to the drawings described below in which like numerals refer to like parts.

FIG. 1 depicts a simplified block diagram illustrating certain features of a memory device, according to embodiments of the present disclosure;

FIG. 2 is a block diagram of the memory banks of the memory device of FIG. 1 having control circuitry, according to embodiments of the present disclosure;

FIG. 3 is a block diagram of column driver circuitry of the memory device of FIGS. 1 and 2, according to embodiments of the present disclosure;

FIG. 4 is a block diagram of a first column driver group of the column driver circuitry of the memory device of FIGS. 1-3 having near and far ground terminals coupled to the column select lines of the memory bank, according to embodiments of the present disclosure;

FIG. 5 is a column driver of the first column driver group of FIG. 4, according to embodiments of the present disclosure;

FIG. 6 is a column driver of the first column driver group of FIG. 4 with a pull-up switch, according to embodiments of the present disclosure;

FIG. 7 is a timing diagram illustrating control signals to control the switches of the column drivers of FIG. 5 or 6 for providing the common supply voltage with two voltage steps, according to embodiments of the present disclosure;

FIG. 8 is a graph illustrating a column select signal generated by the selected column drivers of FIGS. 4-6 having two voltage steps based on control signals of FIG. 7, according to embodiments of the present disclosure;

FIG. 9 is a graph illustrating voltage levels of the column select signal of FIG. 8 generated by the column driver of FIG. 5 or 6 based on control signals of FIG. 7 on the near and far sides of the column select lines of FIG. 4 or 6, according to embodiments of the present disclosure;

FIG. 10 is a second voltage adjustment circuit for adjusting multiple voltage levels of the column drivers of FIG. 4, 5, or 6 based on a column address of target memory cells, according to embodiments of the present disclosure;

FIG. 11 is a second column driver group of the column driver circuitry of the memory device of FIGS. 1-3 generating three-level column select signals, according to embodiments of the present disclosure;

FIG. 12 is a column driver of the second column driver group of FIG. 11, according to embodiments of the present disclosure;

FIG. 13 is a timing diagram illustrating control signals to control the switches of the column drivers of FIGS. 11 and 12 for providing the common supply voltage with three voltage steps, according to embodiments of the present disclosure;

FIG. 14 is a graph illustrating a column select signal of FIGS. 11 and 12 generated by column drivers of FIG. 12 based on the three voltage steps discussed above with respect to FIGS. 11-13, according to embodiments of the present disclosure;

FIG. 15 is a graph illustrating voltage levels of the column select signal of FIG. 14 generated by the column driver of FIG. 12 based on control signals of FIG. 13 on the near and far sides of the column select lines of FIGS. 11 and 12, according to embodiments of the present disclosure;

FIG. 16 is a second voltage adjustment circuit for adjusting multiple voltage levels of the column drivers of FIGS. 11 and 12 based on the column address of the target memory cells, according to embodiments of the present disclosure;

FIG. 17 is a delay circuit for adjusting time durations for providing multiple voltage levels of the column select signals of FIGS. 13-15 based on the column address of the target memory cells, according to embodiments of the present disclosure; and

FIG. 18 is a third column driver group of the column driver circuitry of the memory device of FIGS. 1-3 having separate column select line drivers for targeting near and far memory cells of the memory bank, according to embodiments of the present disclosure.

### DETAILED DESCRIPTION

When introducing elements of various embodiments of the present disclosure, the articles “a,” “an,” and “the” are intended to mean that there are one or more of the elements. The terms “comprising.” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to column driver circuitry of a memory device. A memory bank of the memory device may include multiple memory cells arranged along multiple column select lines and row select lines. The column driver circuitry may include column drivers coupled to the column select lines. A column driver may generate a column select signal with a desired voltage level for accessing a target memory cell coupled to a respective column select line. In some cases, if not compensated for, a resistance and/or parasitic capacitance of the column select line for accessing a target memory cell may reduce the voltage level of the column select signal. For example, the column select line may have an increasingly higher resistance and/or parasitic capacitance for accessing memory cells disposed farther compared to the column driver. The column decoder may include circuitry to adjust a voltage level of the column select signal to provide the desired voltage level to a target memory cell by compensating for the resistance and/or parasitic capacitance for accessing the target memory cell. In some embodiments, the column decoder may include circuitry to adjust the voltage level of the column select signal based on a distance of a target memory cell from the column decoder.

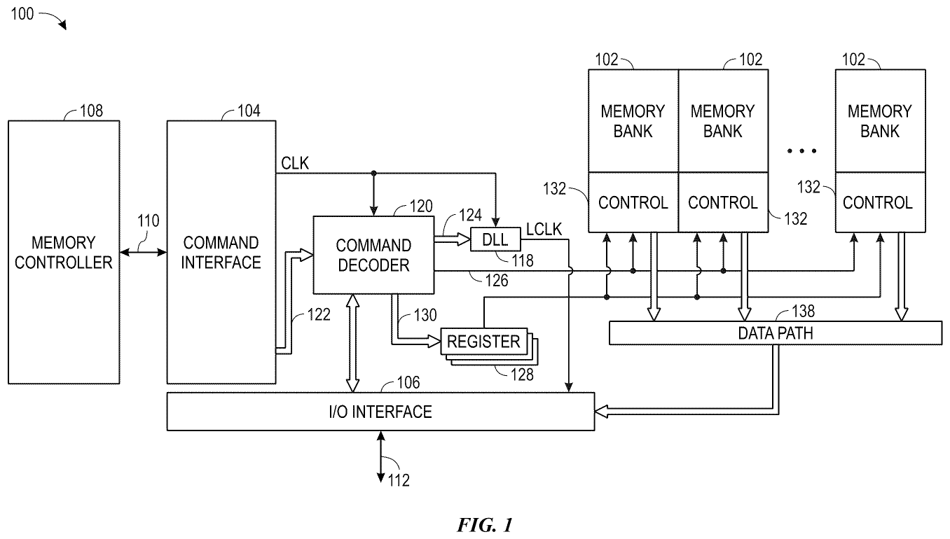

FIG. 1 depicts a simplified block diagram illustrating certain features of a memory device 100 (e.g., a memory subsystem of an apparatus), according to embodiments of the present disclosure. Specifically, the block diagram of FIG. 1 depicts a functional block diagram illustrating certain functionality of the memory device 100. The memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM). Each memory cell of such memory devices may include a corresponding logic storing device (e.g., a capacitor, a resistor, or the resistance of the chalcogenide material(s)).

The memory device 100 may include a number of memory banks 102 each inclusive of one or more memory arrays. Various configurations, organizations, and sizes of the memory banks 102 on the memory device 100 may be used based on an application and/or design of the memory device 100 within an electrical system. For example, in different embodiments, the memory banks 102 may include a different number of rows and/or columns of memory cells. Each memory bank 102 may include a number of segments (e.g., groups) of memory cells. In some embodiments, each segment of a memory bank 102 may include a number of sections (e.g., sub-groups) of memory cells.

The memory device 100 may also include a command interface 104 and an input/output (I/O) interface 106. The command interface 104 is configured to provide a number of signals received from a processor (e.g., a processor subsystem of an apparatus) or a controller, such as a memory controller 108. For example, an electronic device may include the processor coupled to the memory device 100. In different embodiments, the memory controller 108 may include one or more processors (e.g., memory processors), one or more programmable logic fabrics, or any other suitable processing components.

In some embodiments, a bus 110 may provide a signal path or a group of signal paths to allow bidirectional communication between the memory controller 108, the command interface 104 and the I/O interface 106. For example, the memory controller 108 may receive memory access requests from the I/O interface via the command interface 104 and the bus 110. The memory access requests may be indicative of a request for accessing one or more target memory cells. The memory controller 108 may provide commands and/or instructions for performing the memory operations to the command interface 104 via the bus 110.

Similarly, an external bus 112 may provide another signal path or group of signal paths to allow for bidirectional transmission of signals, such as data signals and access commands (e.g., read/write requests), between the I/O interface 106, the memory controller 108, a command decoder 120, and/or other components. Thus, the memory controller 108 may provide various signals (e.g., the access commands, the access instructions, or other signals) to different components of the memory device 100 to facilitate the transmission and receipt of data to be written to or read from the memory banks 102.

The command interface 104 may receive one or more clock signals from an external device (e.g., an external clock signal). The command interface 104 may provide (e.g., generate) an internal clock signal (CLK) based on the one or more clock signals (e.g., the external clock signal). In some embodiments, the command interface 104 may provide the CLK to the command decoder 120 and an internal clock generator, such as a delay locked loop (DLL) 118 circuit. The DLL 118 may generate a phase controlled internal clock signal (LCLK) based on the received CLK. For example, the DLL 118 may provide the LCLK to the I/O interface 106. Subsequently, the I/O interface 106 may use the received LCLK as a clock signal for transmitting the read data using the external bus 112. Moreover, in some cases, the DLL 118 may generate a latching signal and one or more delayed latching signals based on receiving the CLK. In such cases, the DLL 118 may provide the latching signal and the delayed latching signal to the memory banks 102 to facilitate accessing a number of memory cells of one or more of the memory arrays.

The command interface 104 may also provide the internal clock signal CLK to various other memory components. As mentioned above, the command decoder 120 may receive the internal clock signal CLK. In some cases, the command decoder 120 may also receive the access commands via a bus 122 and/or through the I/O interface 106 received via the external bus 112. For example, the command decoder 120 may receive the access commands through the I/O interface 106 transmitted by one or more external devices. In some cases, a processor may transmit the access commands.

The command decoder 120 may decode the access commands and/or the memory access requests to provide corresponding access instructions for accessing the target memory cells. For instance, the command decoder 120 may provide the access instructions to one or more control circuitry 132 associated with the memory banks 102 via a bus path 126. In some cases, the command decoder 120 may provide the access instructions to the control circuitry 132 in coordination with the DLL 118 over a bus 124. For example, the command decoder 120 may coordinate generation of the access instructions in-line (e.g., synchronized) with the CLK and/or LCLK.

The command decoder 120 may decode the access commands (e.g., memory access requests) to provide the access instructions. In some cases, the command decoder 120 may receive the access commands using a rising edge and/or a falling edge of the external clock signal. For example, a processor may transmit the access commands using a memory command protocol such as the multi-clock cycle memory command protocol. Moreover, the processor may use a specific memory command protocol based at least in part on the number of pins of the memory device 100 or the I/O interface 106, the number of rows and/or columns of the memory banks 102, and the number of memory banks 102. Subsequently, the command decoder 120 may provide the access instructions to the memory banks 102 based on receiving and decoding the access commands.

The command decoder 120 may provide the access instructions to the memory banks 102 using one or multiple clock cycles of the CLK via the bus path 126. The command decoder 120 may also transmit various signals to one or more registers 128 via, for example, one or more global wiring lines 130. For example, one of the one or more registers 128 may provide instructions to configure various modes of programmable operations and/or configurations of the memory device 100. Moreover, the memory device 100 may include other decoders, such as row decoders and column decoders, to facilitate access to the memory banks 102, as discussed below.

In some embodiments, each memory bank 102 may include a respective control block 132. In some cases, each of the control circuitry 132 may also provide row decoding and column decoding capability based on receiving the access instructions. Accordingly, the control block 132 may facilitate accessing the memory arrays of the respective memory banks 102. For example, the control circuitry 132 may include circuitry (e.g., logic circuitry) to facilitate accessing the memory cells of one or more memory arrays, segments, and/or sections of the respective memory banks 102 based on receiving the access instructions.

In some cases, the control circuitry 132 may receive the access instructions and determine target memory banks 102 associated with the target memory cells. In specific cases, the command decoder 120 may include the control circuitry 132. Moreover, the control circuitry 132 may also provide timing control and data control functions to facilitate execution of different commands with respect to the respective memory banks 102.

It should be appreciated that in different embodiments, the memory device 100 may include additional or alternative components. That is, the memory device 100 may include additional or alternative components such as power supply circuits (for receiving external VDD and VSS signals), read/write amplifiers (to amplify signals during read/write operations), temperature sensors (for sensing temperatures of the memory device 100), etc. Accordingly, it should be understood that the block diagram of FIG. 1 is only provided to highlight certain functional features of the memory device 100 to aid in the subsequent detailed description.

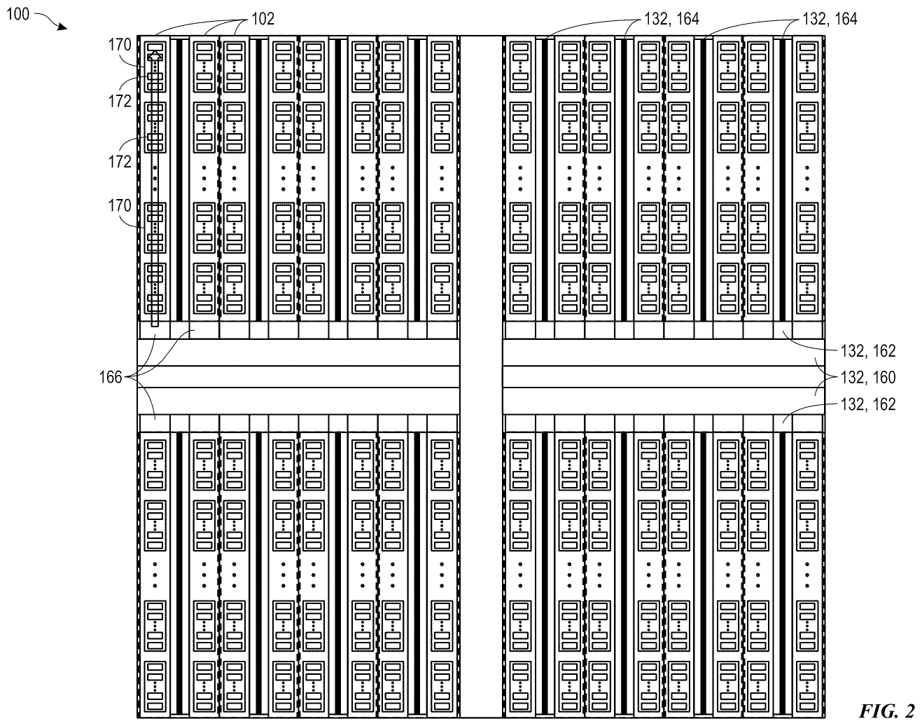

FIG. 2 is a block diagram of the memory banks 102 of the memory device 100 having the control circuitry 132 discussed above, according to embodiments of the present disclosure. The memory device 100 may include the memory banks 102, column decoder circuitry 160, column driver circuitry 162, and row driver circuits 164. In some embodiments, the control circuitry 132 may include the column decoder circuitry 160, the column driver circuitry 162. and/or the row driver circuits 164. The column driver circuitry 162 may include multiple column driver groups 166. Each memory bank 102 may include multiple memory cells arranged along multiple column select lines and row select lines. The column select lines of a memory bank 102 may be coupled to a column driver group 166 on a near side of the memory bank 102. The row select lines of a memory bank 102 may be coupled to a row driver circuit 164. As such, each memory bank 102 may be coupled to a respective column driver group 166 and a row driver circuit 164.

Each column driver group 166 may include circuitry to generate and output column select signals for accessing target memory cells of a respective memory bank 102. For example, the memory controller 108 discussed above may provide instructions to access one or more target memory cells. Each column driver group 166 may generate column select signals 168 for accessing target memory cells based on receiving the instructions. Accessing the target memory cells may include writing data to the target memory cells and/or reading data stored on the target memory cells.

Each memory bank 102 may include multiple segments 170 which in turn include multiple sections 172. Each section 172 may include multiple memory cells. For example, a segment 170 and/or a section 172 may include one or more memory arrays each including multiple memory cells. Moreover, each section 172 of a memory bank 102 is disposed at a different distance from the column driver group 166 coupled to the near side of the memory bank 102. The column driver group 166 may include circuitry to generate a column select signal based on a segment address or a section address of a target memory cell. The column driver group 166 may generate the column select signals with a boosted voltage step. The column driver groups 166 may adjust a voltage level and/or duration of the boosted voltage step of the column select signals based on the segment addresses or section addresses of the target memory cell. For example, the column driver groups 166 may increase a voltage level and/or duration of the boosted voltage step for the segment addresses or section addresses corresponding to target memory cells disposed farther along the column select lines.

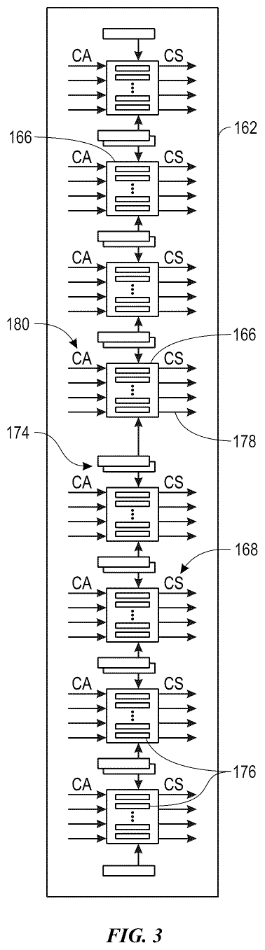

FIG. 3 is the column driver circuitry 162 of the memory device 100 discussed above, according to embodiments of the present disclosure. The column driver circuitry 162 may include power switches 174 and a number of the column driver groups 166. The column driver groups 166 may each include multiple column drivers 176. Each column driver 176 may be coupled to a column select line 178 of the memory bank 102. The column driver groups 166 may receive column addresses 180 (CA) for accessing target memory cells. The column drivers 176 may generate column select signals 168 (CS) for accessing the target memory cells based on receiving the column addresses 180. The column drivers 176 may output the column select signals 168 to respective column select lines 178 coupled thereto to access the target memory cells.

It should be appreciated that in different embodiments, the column driver circuitry 162 may include a different number of column driver groups 166. Moreover, in different embodiments, the column driver groups 166 may include a different number of column drivers 176. In the depicted embodiment, each column driver group 166 may be coupled to two power switches 174. It should be appreciated that in alternative or additional embodiments, each column driver group 166 may be coupled to a different number of power switches 174.

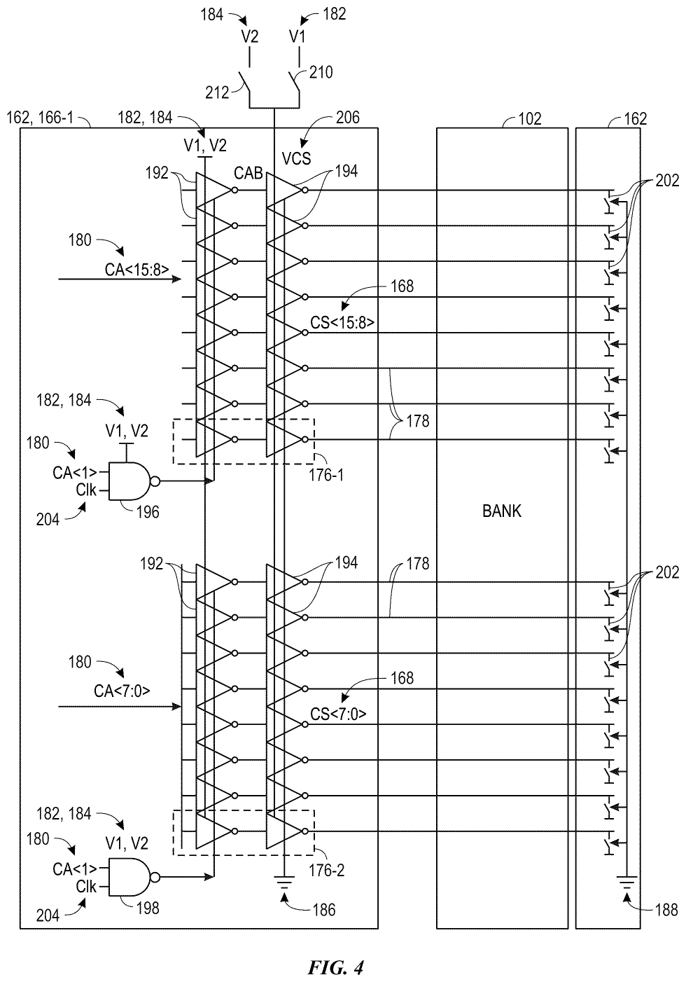

FIGS. 4-10 are directed to some embodiments of column drivers 176 for generating column select signals 168 with a logic high bit having a single voltage step or having two voltage steps. The column drivers 176 may generate the column select signals 168 with the logic high bit to access the target memory cells coupled to the respective column select lines 178. The logic high bit having the single voltage step may have a first voltage level based on a voltage level of a first supply voltage 182 (V1). The logic high bit having the two voltage steps may include a first portion having a second voltage level based on a voltage level of a second supply voltage (V2) followed by a second portion having the first voltage level based on the voltage level of the first supply voltage 182. The voltage level of the second supply voltage 184 may be higher than the voltage level of the first supply voltage 182. In some embodiments, the column drivers 176 may increase a slope of a rising edge of the logic high bit received by the target memory cells by outputting the column select signal 168 with the two voltage steps. Accordingly, in some cases, the target memory cells may receive the logic high bit with a reduced time (e.g., or faster) and/or with a higher voltage level based on the logic high bit having the two voltage steps.

FIG. 4 is a block diagram of a first column driver group 166-1 of the column driver circuitry 162 having near and far ground terminals 186 and 188 coupled to the memory bank 102 via the column select lines 178, according to embodiments of the present disclosure. As mentioned above, each column driver group 166 may include a number of the column drivers 176. In the depicted embodiment, the first column driver group 166-1 may include a number of top column drivers 176-1 and a number of bottom column drivers 176-2. It should be appreciated that in different embodiments, the first column driver group 166-1 may include different circuit components.

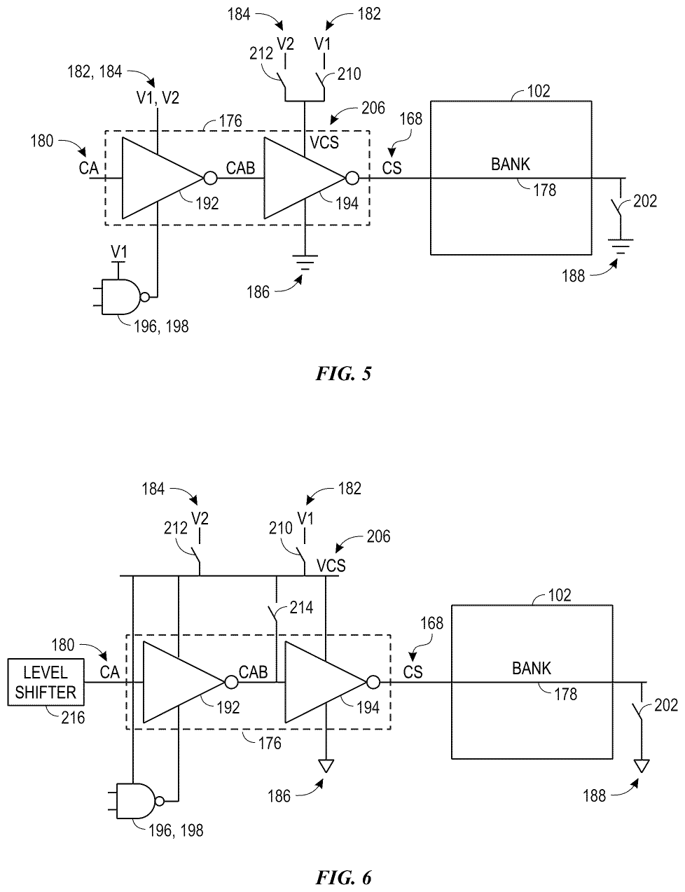

The column drivers 176 may each include a first inverter 192 (e.g., a low voltage driver) and a second inverter 194 (e.g., a low voltage driver, a column select line driver). It should be appreciated that in different embodiments, the column drivers 176 may have different circuitry. Positive supply voltage inputs of the first inverters 192 may be coupled to the first supply voltage 182 or switch between coupling to the first supply voltage 182 and the second supply voltage 184, as will be appreciated. Negative supply voltage inputs of the first inverters 192 of the top column drivers 176-1 may be coupled to a first control logic 196. Negative supply voltage inputs of the first inverters 192 of the bottom column drivers 176-2 may be coupled to a second control logic 198. Supply voltage inputs of the first control logic 196 and the second control logic may couple to (or may be coupled to) the first supply voltage 182 or switch between coupling to the first supply voltage 182 and the second supply voltage 184, as discussed below with respect to FIGS. 5 and 6. It should be appreciated that in alternative or additional embodiments, the first column driver group 166-1 may include a different number of column drivers 176 and/or control logics.

The column driver circuitry 162 may include the first ground terminal 186 coupled to a negative supply voltage input of the second inverters 194. The column driver circuitry 162 may include the second ground terminal 188 that may couple to the column select lines 178 (e.g., an edge of the column select lines 178) at a far side of the memory bank 102. The column driver circuitry 162 may include ground switches 202 to couple and uncouple the column select lines 178 and the second ground terminal 188. The far side of the memory bank 102 may be an opposite side of the memory bank 102 compared to the near side coupled to the column drivers 176 of the first column driver group 166-1. The first ground terminal 186 and the second ground terminal 188 may have a ground voltage.

The first inverters 192 of the top column drivers 176-1 may each input respective bits of a first column address 180 (CA <0>, CA <1>, and so on). The first control logic 196 may activate (e.g., enable) the first inverters 192 of the top column drivers 176-1 based on receiving a logic high portion of a clock signal 204 and a logic high bit with the first column address 180. The logic high bit of the first column address 180 may be indicative of targeting a memory cell coupled to at least one of the top column drivers 176-1. The clock signal 204 may include the internal clock signal and/or the phase controlled internal clock signal discussed above with respect to FIG. 1.

The first control logic 196 may deactivate (e.g., disable) the first inverters 192 of the top column drivers 176-1 based on a lack of the clock signal 204 or receiving a logic low portion of the clock signal 204. Alternatively or additionally, the first control logic 196 may deactivate (e.g., disable) the first inverters 192 of the top column drivers 176-1 based on the first column address 180 being indicative of the memory cells coupled to the top column drivers 176-1 not being targeted. It should be appreciated that a logic high voltage and a logic high bit may correspond a signal or a portion of a signal having a voltage level equal to or above a threshold. Moreover, a logic low voltage and a logic low bit may correspond a signal or a portion of a signal having a voltage level below the threshold. For example, the logic low voltage or the logic low bit may have a voltage level equal to or near a ground voltage level.

The first inverter 192 of the bottom column drivers 176-2 may input respective bits of a second column address 180. The second control logic 198 may activate (e.g., enable) the first inverters 192 of the bottom column drivers 176-2 based on receiving a logic high portion of the clock signal 204 and a logic high bit with the second column address 180. The logic high bit of the second column address 180 may be indicative of targeting a memory cell coupled to at least one of the bottom column drivers 176-2. The second control logic 198 may deactivate (e.g., disable) the first inverters 192 of the bottom column drivers 176-2 based on a lack of the clock signal 204 or receiving a logic low portion of the clock signal 204. Alternatively or additionally, the first control logic 196 may deactivate (e.g., disable) the first inverters 192 of the bottom column drivers 176-2 based on the second column address 180 being indicative of the memory cells coupled to the bottom column drivers 176-2 not being targeted.

As mentioned above, the positive supply voltage inputs of the first inverters 192 may receive the first supply voltage 182. The first inverters 192 may become activated to invert an input signal when receiving the first supply voltage 182. Moreover, the first inverters 192 of a column driver 176 coupled to a target memory cell may input a logic high bit of the column address 180. In some cases, the top column drivers 176-1 and/or the bottom column drivers 176-2 may each receive a portion of (e.g., a bit of) the column address 180 in parallel. In some embodiments, the logic high bit may have a voltage level equal to (nearly equal to) a voltage level of the first supply voltage 182. The activated first inverters 192 may output a logic low bit (CAB) to the second inverter 194 coupled thereto based on inputting the logic high bit of the column address 180.

The second inverters 194 that are coupled to a target memory cell may input the logic low bit generated by the first inverters 192. Positive supply voltage inputs of the second inverters 194 may receive a common supply voltage 206 (e.g., a voltage common-source (VCS)). The second inverters 194 may become activated to invert an input signal when receiving the common supply voltage 206. As such, the second inverters 194 may generate the column select signals 168 having a logic high bit based on inputting the logic low bit and receiving the common supply voltage 206. The second inverters 194 may generate the column select signals 168 having a voltage level based on a voltage level of the common supply voltage 206, as will be appreciated. The activated second inverters 194 inputting the logic low bit may output the column select signals 168 to the respective column select lines 178 for accessing the target memory cell of the memory bank 102. Accordingly, the column driver circuitry 162 may output the column select signal 168 to the selected column select lines 178 based on the column address 180.

In the depicted embodiment, the common supply voltage 206 may have a high voltage level having a single voltage step or switching between two voltage steps. As mentioned above, the second inverters 194 may generate the column select signals 168 having a voltage level based on a voltage level of the common supply voltage 206. In particular, the second inverters 194 may generate the column select signals 168 based on voltage levels of the common supply voltage 206 received at the respective positive supply voltage inputs when the respective negative supply voltage inputs are coupled to the first ground terminal 186. As such, the second inverters 194 may generate the logic high bit of the column select signals 168 with a single voltage step or two voltage steps based on the voltage levels of the common supply voltage 206.

The column driver circuitry 162 (or the first column driver group 166-1) may include a first switch 210 coupled to the first supply voltage 182 and a second switch 212 coupled to the second supply voltage 184. The first switch 210 may couple and uncouple the first supply voltage 182 and the positive supply voltage inputs of the second inverters 194. The second switch 212 may couple and uncouple the second supply voltage 184 and the positive supply voltage inputs of the second inverters 194. In some cases, the first switch 210 may couple the first supply voltage 182 to the second inverters 194 to provide the single voltage step. Alternatively, the second switch 212 may couple the second supply voltage 184 to the second inverters 194 to provide the single voltage step. As such, the single voltage step may have a voltage level of the first supply voltage 182 or the second supply voltage 184 based on a position of the first switch 210 and the second switch 212.

The two voltage steps may include a first voltage step having a voltage level based on a voltage level of the second supply voltage 184 followed by a second voltage step having a voltage level based on a voltage level of the first supply voltage 182. The second switch 212 may couple the second supply voltage 184 to the second inverters 194 during the first voltage step. The first switch may be open during the first voltage step. Moreover, the first switch 210 may couple the first supply voltage to the second inverters 194 during the second voltage step. The second switch 212 may be open during the second voltage step. For example, the memory controller 108 discussed above may generate control signals to open and close the first switch 210 and the second switch 212 to provide the common supply voltage 206 with one or two voltage levels. Alternatively or additionally, any other viable circuitry may generate the control signals, for example, based on receiving the column address 180.

As mentioned above, the second supply voltage 184 may have a higher voltage level compared to the first supply voltage 182. Moreover, the column drivers 176 may generate the column select signals 168 with the second voltage level based on a voltage level of the second supply voltage 184 followed by the first voltage level based on a voltage level of the first supply voltage 182. As such, in some cases, the column drivers 176 may increase a slope of a rising edge of the logic high bit by outputting the column select signal 168 with the two voltage steps having the second voltage level followed by the first voltage level compared to outputting the column select signal 168 with the single voltage step having the first voltage level. For example, the target memory cells may receive the logic high bit (or the column select signal 168) having the two voltage steps with a reduced time (e.g., or faster) and/or with a higher voltage level compared to receiving the logic high bit (or the column select signal 168) having the single voltage step.

The first inverters 192 may input a logic low bit of the column address 180 when the respective column drivers 176 are not selected by the column address 180. Each of the first inverters 192 may output a logic high signal to the respective second inverters 194 based on inputting a logic low bit of the column address 180. The second inverters 194 may couple the column select lines 178 to the first ground terminal 186 based on inputting the logic high signal. Moreover, the ground switches 202 may couple the second ground terminal 188 to opposite sides of the respective column select lines 178 at a far side of the memory bank 102. Accordingly, the column driver circuitry 162 may ground the near and the far sides of (e.g., both edges of) the respective column select lines 178. For example, such column select lines 178 may not be coupled to a target memory cell.

For example, the ground switches 202 may receive an indication to couple the respective column select line 178 to the second ground terminal 188 when the respective column select line 178 is not coupled to a target memory cell. By way of example, each of the ground switches 202 may be coupled to the first inverter 192 and/or the second inverter 194 coupled to the respective column select line 178 to receive the indication. Alternatively or additionally, the ground switches 202 may be coupled to the memory controller 108 discussed above to receive the indication. The ground switch 202 may couple the second ground terminal 188 to the column select line X based on receiving the indication. It should be appreciated that in some embodiments, the column driver circuitry 162 may not include the ground switches 202.

In some embodiments, the column driver circuitry 162 may couple the near and far sides of the unselected column select lines 178 to the ground voltage. Moreover, the column driver circuitry 162 may couple the near and far sides of the selected column select lines 178 to the ground voltage after outputting the column select signal 168 and/or after inputting the respective logic high bits of the column address 180. For example, the column drivers 176 of the selected column select lines 178 may input a logic low voltage after inputting the logic high bit of the column address 180. The column driver circuitry 162 may increase a slope of a falling edge of the column select signal 168 based on coupling the near and far sides of the column select lines 178 to the ground voltage. Accordingly, the target memory cells may receive the ground voltage at a reduced time (e.g., or faster) by grounding both the near and far sides of the column select lines 178.

FIG. 5 is a column driver 176 of the first column driver group 166-1 described above, according to embodiments of the present disclosure. The column driver 176 may include the first inverter 192 and the second inverter 194 coupled to the memory bank 102 via a column select line 178. The positive supply voltage input of the first inverter 192 may be coupled to the common supply voltage 206. The negative supply voltage input of the first inverter 192 may be coupled to the first control logic 196 or the second control logic 198. The supply voltage input of the first control logic 196 or the second control logic 198 may be coupled to the first supply voltage 182. The first switch 210 may couple the first supply voltage 182 to the positive supply voltage input of the second inverter 194. The second switch 212 may couple the second supply voltage 184 to the positive supply voltage input of the second inverter 194. The ground switch 202 may couple the far side of the column select line 178 to the second ground terminal 188.

The first inverter 192 may generate a logic low bit based on inputting a logic high bit of the column address 180 selecting the column driver 176. The second inverter 194 may generate the column select signal 168 with a logic high bit. In some cases, the logic high bit of the column select signal 168 may have two voltage steps. The column select signal 168 may have a first voltage step having a voltage level based on a voltage level of the second supply voltage 184 followed by a second voltage step having a voltage level based on a voltage level of the first supply voltage 182. The voltage level of the first voltage step may be higher than the voltage level of the second voltage step. Moreover, the second inverter 194 and the ground switch 202 may couple the near and far sides of the column select line 178 to ground voltage after outputting the column select signal 168.

FIG. 6 is a column driver 176 of the first column driver group 166-1 described above with a pull-up switch 214, according to embodiments of the present disclosure. The column driver 176 may include the first inverter 192 and the second inverter 194 coupled to the memory bank 102 via the column select line 178. The positive supply voltage input of the first inverter 192 and the second inverter 194 may be coupled to the common supply voltage 206. The negative supply voltage input of the first inverter 192 may be coupled to the first control logic 196 or the second control logic 198. The negative supply voltage input of the second inverter 194 may be coupled to the first ground terminal 186. Moreover, the supply voltage input of the first control logic 196 or the second control logic 198 may be coupled to the common supply voltage 206.

In some embodiments, a level shifter 216 may output the logic high bit of the column address 180 selecting the column driver 176 to the first inverter 192. In some cases, the level shifter 216 may provide the logic high bit based on a voltage level first supply voltage 182 and/or the second supply voltage 184. For example, the level shifter 216 may up-convert the voltage level of the column address 180 when the common supply voltage 206 is coupled to the second supply voltage 184. The control circuitry 132 and/or the column decoder circuitry 160 of the memory device 100 discussed above with respect to FIGS. 1 and 2 may include the level shifter 216. As such, the first inverter 192, the second inverter 194, and the control logic 196 or 198 may operate based on voltage levels of the common supply voltage 206.

The first switch 210 may couple the first supply voltage 182 to the positive supply voltage inputs of the first inverter 192 and the second inverter 194 and the supply voltage input of the control logic 196 or 198. The second switch 212 may couple the second supply voltage 184 to the positive supply voltage inputs of the first inverter 192 and the second inverter 194 and the supply voltage input of the control logic 196 or 198. The column driver circuitry 162 may include the pull-up switch 214 coupled to the first switch 210, the second switch 212, the output port of the first inverter 192, and the input port of the second inverter 194. Moreover, the ground switch 202 may couple the far side of the column select line 178 to the second ground terminal 188. It should be appreciated that in some embodiments, the column driver circuitry 162 may not include the ground switch 202.

The pull-up switch 214 may include a p-channel metal-oxide semiconductor (pMOS) transistor, among other possibilities. In some cases, the pull-up switch 214 may synchronize or pull-up the voltage level at the output port of the first inverter 192 and the input port of the second inverter 194 based on the voltage level of the common supply voltage 206. In some cases, the pull-up switch 214 may close based on receiving a gate voltage corresponding to the voltage level of (e.g., an instant voltage level) the common supply voltage 206. That is, the pull-up switch 214 may receive voltage levels having the same voltage as, being an inverse of, a portion of, and/or a multiplication of the voltage level of the common supply voltage 206. For example, the pull-up switch 214 may receive a voltage level corresponding to a voltage level of the first supply voltage 182 when the first switch is closed and may receive a voltage level corresponding to a voltage level of the second supply voltage 184 when the second switch is closed.

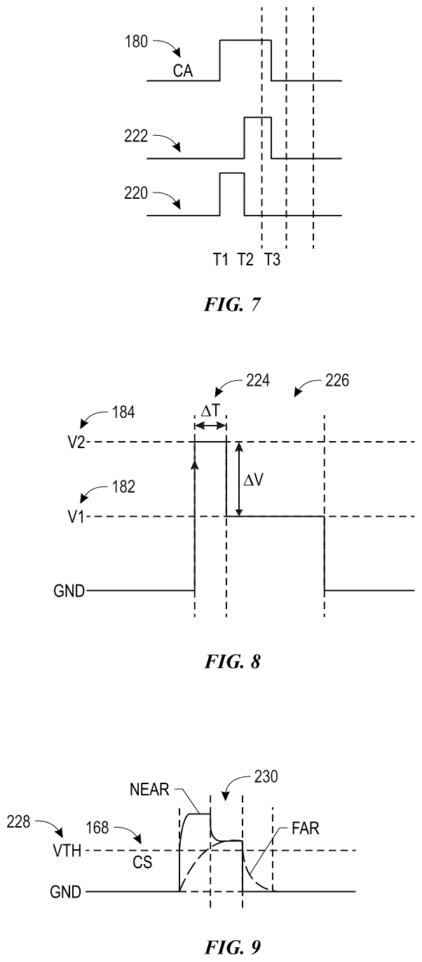

FIG. 7 is a timing diagram illustrating control signals 220 and 222 to control the switches 210 and 212 for providing the common supply voltage 206 with two voltage steps by the column driver 176 of FIG. 5 or 6 discussed above, according to embodiments of the present disclosure. The first switch 210 and the second switch 212 may receive the first control signal 220 and the second control signal 222 respectively. By way of example, the first switch 210 and the second switch 212 may each include pMOS transistors. The column driver 176 (e.g., the first inverter 192) may receive a rising edge of the logic high bit of the column address 180 at a time T1.

During a time period between times T1 and T2, the first control signal 220 may have a high voltage level and the second control signal 222 may have a low voltage level. As such, the first switch 210 may be open and the second switch 212 may be closed. The second inverter 194 of the column drivers 176 may be coupled to the second supply voltage 184 during the time period between the times T1 and T2. Moreover, the column driver 176 (e.g., the first inverter 192, the second inverter 194) may receive a portion of the logic high bit of the column address 180. Accordingly, the second inverter 194 may generate the column select signal 168 with the second voltage level based on a voltage level of the second supply voltage 184 during the time period between the times T1 and T2.

During a time period between times T2 and T3, the first control signal 220 may have a low voltage level and the second control signal 222 may have a high voltage level. As such, the first switch 210 may be closed and the second switch 212 may be open. The second inverter 194 of the column drivers 176 may be coupled to the first supply voltage 182 during the time period between the times T2 and T3. Moreover, the column driver 176 (e.g., the first inverter 192, the second inverter 194) may receive a remaining portion of the logic high bit of the column address 180. Accordingly, the second inverter 194 may generate the column select signal 168 with the first voltage level based on a voltage level of the first supply voltage 182 during the time period between the times T2 and T3.

The column driver 176 (e.g., the first inverter 192) may receive a falling edge of the logic high bit of the column address 180 at the time T3. As such, the second inverter 194 and the ground switch 202 may couple the near and far sides of the column select line 178 to the ground voltage. It should be appreciated that time periods between T1 and T2 and between T2and T3 may be different in different embodiments. Moreover, it should be appreciated that in alternative or additional embodiments, the first switch 210 and the second switch 212 of the column drivers 176 may each include a different switching circuit and/or transistor type. In such alternative or additional embodiments, the first control signal 220 and the second control signal 222 may be different based on the switching circuit and/or transistor type of the first switch 210 and the second switch 212. For example, the first control signal 220 and the second control signal 222 may each be inverted, delayed, or have different voltage levels and/or relative timings.

FIG. 8 is a graph illustrating the column select signal 168 generated by the selected column drivers 176 based on the two voltage steps discussed above with respect to FIGS. 4-7, according to embodiments of the present disclosure. In some embodiments, the column select signal 168 may initially have the voltage level (V2) of the second supply voltage 184 based on the second inverter 194 coupling to the second inverter 194. The common supply voltage 206 may subsequently have the voltage level (V1) of the first supply voltage 182 based on the second inverter 194 coupling to the first supply voltage 182. A voltage level difference (AV) between the voltage levels of the first supply voltage 182 and the second supply voltage 184 may be adjusted by a first voltage adjustment circuit. A time duration (AT) for providing the voltage level of the second supply voltage may be adjusted by a delay circuit.

FIG. 9 is a graph illustrating voltage levels of the column select signal 168 generated by the column driver 176 (e.g., the second inverter 194) of FIG. 5 or 6 based on control signals 220 and 222 of FIG. 7 on the near and far sides of the column select line 178, according to embodiments of the present disclosure. In particular, the graph illustrates the two voltage steps of the column select signal 168 at or near the near side of the memory bank 102 and at or near the far side of the memory bank 102. The column select signal 168 may have a first voltage step 224 having a voltage level based on the voltage level of the second supply voltage 184 followed by a second voltage step 226 having a voltage level based on the voltage level of the first supply voltage 182. The voltage level of the first voltage step 224 may be higher than the voltage level of the second voltage step 226.

A resistance and/or parasitic capacitance of the column select line 178 for accessing a target memory cell may reduce the voltage level of the column select signal 168. For example, the column select line 178 may have a higher resistance and/or parasitic capacitance for accessing target memory cells disposed near the far side of the memory bank 102 compared to accessing target memory cells disposed near the near side of the memory bank 102. Moreover, the target memory cells may be accessed based on receiving a column select signal 168 with a voltage level equal to or above a voltage threshold 228 (e.g., a threshold voltage level) for a time period equal to or above a desired time 230.

The first voltage step 224 and the second voltage step 226 may have voltage levels above the voltage threshold 228. The higher voltage level of the first voltage step 224 of the column select signal 168 may compensate for at least a portion of the resistance and/or parasitic capacitance for accessing the target memory cells disposed (or coupled to the column select line 178) near the far side of the memory bank 102. In some cases, the higher voltage level of the first voltage step 224 may increase a rising edge slope or time of the column select signal 168 at or near the far side of the memory bank 102. As such, the target memory cells coupled to the column select line 178 at or near the far side of the memory bank 102 may receive the column select signal 168 with a voltage level equal to or above the voltage threshold 228 for a time period equal to or above the desired time 230. Moreover, the second inverter 194 and the ground switch 202 may couple the near and far sides of the column select line 178 to ground voltage after outputting the column select signal 168.

In some embodiments, based on the two voltage steps of the logic high bit of the column select signal 168, the column select line 178 may be coupled to additional memory cells to increase a capacity of the memory bank 102. In specific embodiments, the first voltage adjustment circuit may adjust the voltage level of the second supply voltage 184 based on a length of the column select line 178 or a disposition of the target memory cells along the column select line 178. In alternative or additional embodiments, the delay circuit may adjust the time duration (AT) for providing the voltage level of the second supply voltage 184 based on the length of the column select line 178 or the disposition of the target memory cells along the column select line 178. For example, the first voltage adjustment circuit and/or the delay circuit may adjust the voltage level of and/or the time duration (ΔT) for providing the voltage level of the second supply voltage 184 based on the column address 180 of the target memory cell, segment addresses or section addresses of the target memory cell, among other possibilities.

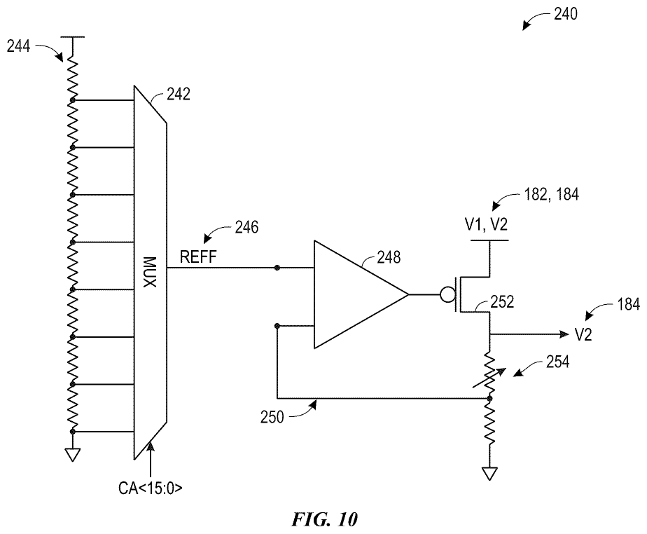

FIG. 10 is a first voltage adjustment circuit 240 for adjusting a voltage level of the second supply voltage 184 based on the column address 180, according to embodiments of the present disclosure. The first voltage adjustment circuit 240 may include a multiplexer 242 receiving the column address 180 associated with the first column driver group 166-1. Input ports of the multiplexer 242 may each be coupled to a different resistor or between different resistors of a resistor string 244. The resistor string 244 may be coupled to a voltage source on one side and to a ground terminal on the other side. The voltage source may include the first supply voltage 182 or any other viable voltage source of the memory device 100 of FIG. 1.

The multiplexer 242 may generate a reference voltage 246 (REF) by selecting an input port based on the column address 180. In specific non-limiting cases, the column address 180 may indicate targeting a single memory cell or one or more memory cells of a single memory section or memory segment. In some embodiments, the multiplexer 242 may have a number of input ports corresponding to a number of the segments or sections of the memory bank 102 discussed above. For example, the multiplexer 242 may select an input port corresponding to a segment address or section address of the target memory cell based on the column address 180. Alternatively or additionally, the multiplexer 242 may receive the segment address or section address in lieu of or in addition to receiving the column address 180. In some embodiments, the first voltage adjustment circuit 240 (and/or the multiplexer 242) may include a lookup table to select the input port coupled to the resistor string 244 based on the segment address, the section address, and/or the column address 180. A first amplifier 248 may receive the reference voltage 246 and a first feedback signal 250. The first amplifier 248 may generate a gate voltage of an output switch 252. The output switch 252 may include a pMOS transistor, an n-channel metal-oxide semiconductor (nMOS) transistor, among other possibilities.

The output switch 252 may be coupled to a voltage source on one side and to a ground terminal via one or more first feedback resistors 254 on the other side. The first amplifier 248 may receive the first feedback signal 250 from the first feedback resistors 254. The voltage source may include the first supply voltage 182 or any other viable voltage source of the memory device 100 of FIG. 1. The output switch 252 may output the second supply voltage 184. As such, the first voltage adjustment circuit 240 may provide the second supply voltage 184 with a voltage level based on the column address 180 and/or the segment address or section address of the target memory cell. As such, the first voltage adjustment circuit 240 may adjust the voltage level difference (ΔV) between the voltage levels of the first supply voltage 182 and the second supply voltage 184. It should be appreciated that in different embodiments, the first voltage adjustment circuit 240 may include different circuitry to provide the second supply voltage 184 based on the column address 180 and/or the segment address or section address of the target memory cell.

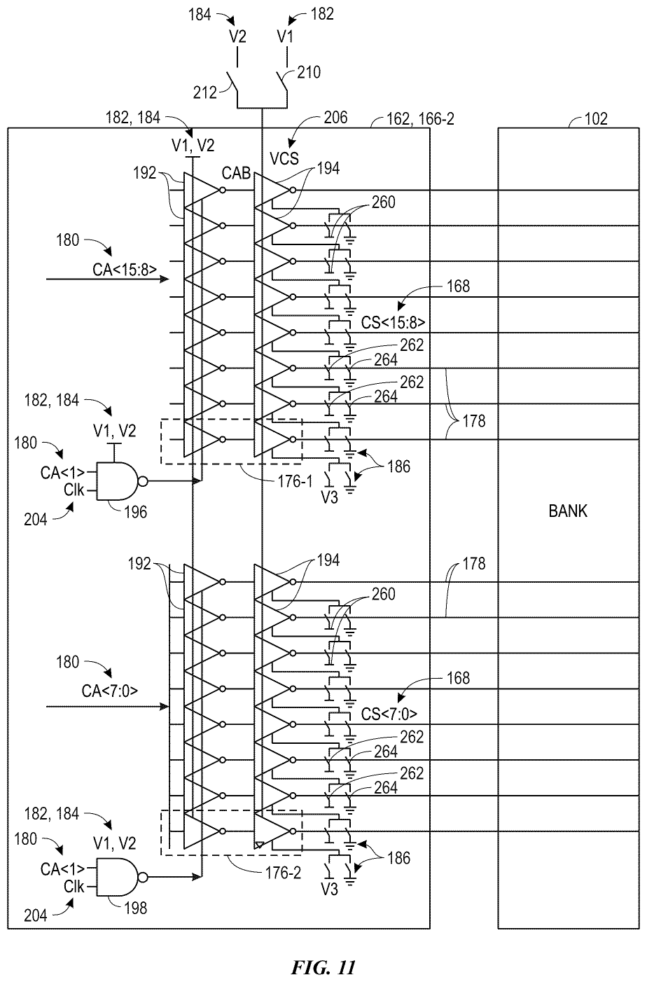

FIGS. 11-17 are directed to some embodiments of column drivers 176 for generating column select signals 168 with a logic high bit having three voltage steps. The column drivers 176 may generate the column select signals 168 with the logic high bit to access the target memory cells coupled to the respective column select lines 178. The logic high bit having the three voltage steps may include a first portion followed by a second portion and a third portion. The first portion may have the second voltage level based on the voltage level of the second supply voltage 184. The voltage level of the first supply voltage 182 may be higher than the ground voltage. The second portion may have the first voltage level based on the voltage level of the first supply voltage 182. The voltage level of the second supply voltage 184 may be higher than the voltage level of the first supply voltage 182. The third portion may have a third voltage level based on a voltage level of a third supply voltage 260. The voltage level of the third supply voltage 260 may be lower than the ground voltage (e.g., a negative voltage level). In some embodiments, the column drivers 176 may increase a slope of a rising edge of the logic high bit received by the target memory cells by outputting the column select signal 168 with the three voltage steps. Accordingly, in some cases, the target memory cells may receive the logic high bit with a reduced time (e.g., or faster) and/or with a higher voltage level based on the logic high bit having the three voltage steps.

FIG. 11 is a block diagram of a second column driver group 166-2 of the column driver circuitry 162 generating three-level column select signals 168 coupled to the memory bank 102 via the column select lines 178, according to embodiments of the present disclosure. As mentioned above, each column driver group 166 may include a number of the column drivers 176. In the depicted embodiment, the second column driver group 166-2 may include the number of top column drivers 176-1 and the number of bottom column drivers 176-2. It should be appreciated that in different embodiments, the second column driver group 166-2 may include different circuit components.

As discussed above, the column drivers 176 may each include the first inverter 192 and the second inverter 194. It should be appreciated that in different embodiments, the column drivers 176 may have different circuitry. Positive supply voltage inputs of the first inverters 192 may be coupled to the first supply voltage 182. Negative supply voltage inputs of the first inverters 192 of the top column drivers 176-1 may be coupled to the first control logic 196. Negative supply voltage inputs of the first inverters 192 of the bottom column drivers 176-2 may be coupled to the second control logic 198. Supply voltage inputs of the first control logic 196 and the second control logic may couple to (or may be coupled to) the first supply voltage 182 or switch between coupling to the first supply voltage 182 and the second supply voltage 184, as discussed above with respect to FIGS. 5-7. It should be appreciated that in alternative or additional embodiments, the second column driver group 166-2 may include a different number of column drivers 176 and/or control logics.

The first inverters 192 of the top column drivers 176-1 may each input respective bits of the first column address 180 (CA). The first control logic 196 may activate (e.g., enable) the first inverters 192 of the top column drivers 176-1 based on receiving a logic high portion of the clock signal 204 and a logic high bit with the first column address 180. The logic high bit of the first column address 180 may be indicative of targeting a memory cell coupled to at least one of the top column drivers 176-1. The first control logic 196 may deactivate (e.g., disable) the first inverters 192 of the top column drivers 176-1 based on a lack of the clock signal 204 or receiving a logic low portion of the clock signal 204. Alternatively or additionally, the first control logic 196 may deactivate (e.g., disable) the first inverters 192 of the top column drivers 176-1 based on the first column address 180 being indicative of the memory cells coupled to the top column drivers 176-1 not being targeted.

The first inverter 192 of the bottom column drivers 176-2 may each input respective bits of the second column address 180. The second control logic 198 may activate (e.g., enable) the first inverters 192 of the bottom column drivers 176-2 based on receiving a logic high portion of the clock signal 204 and a logic high bit with the second column address 180. The logic high bit of the second column address 180 may be indicative of targeting a memory cell coupled to at least one of the bottom column drivers 176-2. The second control logic 198 may deactivate (e.g., disable) the first inverters 192 of the bottom column drivers 176-2 based on a lack of the clock signal 204 or receiving a logic low portion of the clock signal 204. Alternatively or additionally, the first control logic 196 may deactivate (e.g., disable) the first inverters 192 of the bottom column drivers 176-2 based on the second column address 180 being indicative of the memory cells coupled to the bottom column drivers 176-2 not being targeted.

As mentioned above, the positive supply voltage inputs of the first inverters 192 may receive the first supply voltage 182. The first inverters 192 may become activated to invert an input signal when receiving the first supply voltage 182. Moreover, the first inverters 192 of a column driver 176 coupled to a target memory cell may input a logic high bit of the column address 180. In some cases, the top column drivers 176-1 and/or the bottom column drivers 176-2 may each receive a portion of (e.g., a bit of) the column address 180 in parallel. In some embodiments, the logic high bit may have a voltage level equal to (nearly equal to) a voltage level of the first supply voltage 182. The activated first inverters 192 may output a logic low bit (CAB) to the second inverter 194 coupled thereto based on inputting the logic high bit of the column address 180.

The positive supply voltage input of each second inverter 194 may be coupled to the first switch 210 and the second switch 212. The positive supply voltage input of the second inverters 194 may couple to the first supply voltage 182 via the first switch 210 and may couple to the second supply voltage 184 via the second switch 212. In the depicted embodiment, the negative supply voltage input of each second inverter 194 may be coupled to a respective third switch 262 and a respective fourth switch 264. The negative supply voltage input of each second inverter 194 may couple to (e.g., may individually couple to) the third supply voltage 260 via the respective third switch 262 and may couple to (e.g., may individually couple to) the first ground terminal 186 via the respective fourth switch 264.

The second inverters 194 that are coupled to a target memory cell may input the logic low bit generated by the first inverters 192. Positive supply voltage inputs of the second inverters 194 may receive the common supply voltage 206 (VCS) by coupling to the first supply voltage 182 and/or the second supply voltage 184. The second inverters 194 may become activated to invert an input signal when receiving the common supply voltage 206. As such, the second inverters 194 may generate the column select signals 168 having a logic high bit based on inputting the logic low bit and receiving the common supply voltage 206.

The second inverters 194 may generate the column select signals 168 having a voltage level based on a voltage level of the common supply voltage 206. The activated second inverters 194 inputting the logic low bit may output the column select signals 168 to the respective column select lines 178 for accessing the target memory cell of the memory bank 102. Accordingly, the column driver circuitry 162 may output the column select signal 168 to the selected column select lines 178 based on the column address 180.

As mentioned above, the second inverters 194 may generate the column select signals 168 having a voltage level based on a voltage level of the common supply voltage 206. In particular, the second inverters 194 may generate the column select signals 168 based on voltage levels of the common supply voltage 206 received at the respective positive supply voltage inputs. In the depicted embodiment, the common supply voltage 206 may have a high voltage level having the single voltage step, the two voltage steps, or three voltage steps. The single voltage step may have a voltage level of the first supply voltage 182 or the second supply voltage 184. Moreover, the two voltage steps may include the first voltage step having the voltage level of the second supply voltage 184 followed by the second voltage step having the voltage level of the first supply voltage 182.

The three voltage steps may include the first voltage step followed by a second voltage step having the voltage level of the first supply voltage 182 and a third voltage step having a voltage level of a third supply voltage 260. In some embodiments, the memory controller 108 discussed above may generate control signals to open and close the first switch 210, the second switch 212, the third switches 262, and the fourth switches 264. Alternatively or additionally, any other viable circuitry may generate the control signals, for example, based on receiving the column address 180.

The second switch 212 may couple the second supply voltage 184 to the positive supply voltage input of the second inverters 194 of the second column driver group 166-2 during the first voltage step of the three voltage steps. As such, the second switch 212 may couple the second supply voltage 184 to the positive supply voltage input of the second inverters 194 during the first voltage step of any activated second inverters 194 of the second column driver group 166-2.

For example, the second switch 212 may remain closed during a first time duration (ΔT1) of the first voltage step in response to a rising edge of the column addresses 180 (e.g., any of the column addresses 180) of the second column driver group 166-2 (e.g., CA <15:0>). Moreover, the fourth switch 264 of the activated second inverters 194 (e.g., of each of the activated second inverters 194) may couple the first ground terminal 186 to the negative supply voltage input of the activated second inverters 194 during the first voltage step. For example, the fourth switch 264 of the activated second inverters 194 and the second switch 212 may remain closed during the first time duration (ΔT1) in response to a rising edge of the column addresses 180 of the selected column drivers 176 (e.g., CA <0>, CA <1>, and/or so on). The third switches 262 of the activated second inverters 194 and the first switch 210 may be (e.g., remain) open during the first voltage step.

The activated second inverters 194 may input the logic low bit generated by the first inverters 192 based on a logic high bit of the respective column address 180 (e.g., CA <0>, CA <1>, and/or so on). As such, the activated second inverters 194 may output a first portion of the column select signal 168 having a voltage level based on a voltage level of the second supply voltage 184. For example, the activated second inverters 194 may couple the respective column select line 178 to the second supply voltage 184. In some cases, the selected column driver 176 may output a positive voltage level higher than the ground voltage based on a voltage level of the second supply voltage 184.

The first switch 210 may couple the first supply voltage 182 to the positive supply voltage input of the second inverters 194 of the second column driver group 166-2 during the second voltage step of the three voltage steps. As mentioned above, the first switch 210 may be coupled to the positive supply voltage input of the second inverters 194 of the second column driver group 166-2. As such, the first switch 210 may couple the first supply voltage 182 to the positive supply voltage input of the second inverters 194 during the second voltage step of any activated second inverters 194 of the second column driver group 166-2. Moreover, the third switch 262 of the activated second inverters 194 (e.g., of each of the activated second inverters 194) may couple the third supply voltage 260 to the negative supply voltage input of the activated second inverters 194 during the second voltage step. The fourth switches 264 of the activated second inverters 194 and the second switch 212 may be (e.g., remain) open during the second voltage step.

The activated second inverters 194 may input the logic low bit generated by the first inverters 192 based on a logic high bit of the respective column address 180 (e.g., CA <0>, CA <1>, and/or so on). As such, the activated second inverters 194 may output a second portion of the column select signal 168 having a voltage level based on a voltage level of the first supply voltage 182. For example, the activated second inverters 194 may couple the respective column select line 178 to the first supply voltage 182. In some cases, the selected column driver 176 may output a positive voltage level lower than that of the first portion of the column select signal 168 discussed above based on a voltage level of the first supply voltage 182 being lower than that of the second supply voltage 184.

The first switch 210 may remain closed during the third voltage step of any activated second inverters 194 of the second column driver group 166-2 during the third voltage step of the three voltage steps. For example, the first switch 210 may remain closed for a second time duration (ΔT2) of the third voltage step in response to or after a falling edge of the column addresses 180 (e.g., any of the column addresses 180, all of the column addresses 180, CA <15: 0>). Moreover, the third switch 262 of the activated second inverters 194 (e.g., of each of the activated second inverters 194) may remain closed during the third voltage step. For example, the third switch 262 of the activated second inverters 194 and the first switch 210 may remain closed for the second time duration (ΔT2) in response to a falling edge of the column addresses 180 of the selected column drivers 176 (e.g., any of the column addresses 180, all of the column addresses 180, CA <15: 0>). The fourth switches 264 of the activated second inverters 194 and the second switch 212 may be (e.g., remain) open during the third voltage step.

The activated second inverters 194 may input the logic high bit generated by the first inverters 192 based on a logic low bit of the respective column address 180 (e.g., CA <0>, CA <1>, and/or so on). As such, the activated second inverters 194 may output a third portion of the column select signal 168 having a voltage level based on a voltage level of the third supply voltage 260. For example, the activated second inverters 194 may couple the respective column select line 178 to the third supply voltage 260. In some cases, the selected column driver 176 may output a negative voltage level lower than the ground voltage based on a voltage level of the third supply voltage 260. As such, the second inverters 194 may output the three voltage steps of the column select signal 168 based on receiving three different voltage levels (e.g., differential voltage levels) at the respective supply voltage inputs. In some cases, the second inverters 194 may output he ground voltage after outputting the third portion of the column select signal 168.

As mentioned above, the second supply voltage 184 may have a higher voltage level compared to the first supply voltage 182 that is higher than the ground voltage. The third supply voltage 260 may have a voltage level lower than the ground voltage. Moreover, as discussed above, the column drivers 176 may generate the column select signals 168 with the second voltage level based on the voltage level of the second supply voltage 184 followed by the first voltage level based on the voltage level of the first supply voltage 182 and the third voltage level based on the voltage level of the third supply voltage 260. In some cases, the column drivers 176 may improve (e.g., increase) slopes of the rising edges and the falling edges of the column select signals 168 based on generating the common supply voltage 206 with the three voltage steps. For example, the target memory cells may receive the logic high bit (or the column select signal 168) having the three voltage steps with a reduced time (e.g., or faster) and/or with a higher voltage level compared to receiving the logic high bit (or the column select signal 168) having the single voltage step.

As mentioned above, the first inverters 192 may input a logic low bit of the column address 180 when the respective column drivers 176 are not selected by the column address 180. Each of the first inverters 192 may output a logic high signal to the respective second inverters 194 based on inputting a logic low bit of the column address 180. Each of the second inverters 194 inputting the logic high signal may couple the column select lines 178 to the first ground terminal 186 via the respective fourth switches 264. Accordingly, the column driver circuitry 162 may ground the respective column select lines 178. For example, such column select lines 178 may not be coupled to a target memory cell.

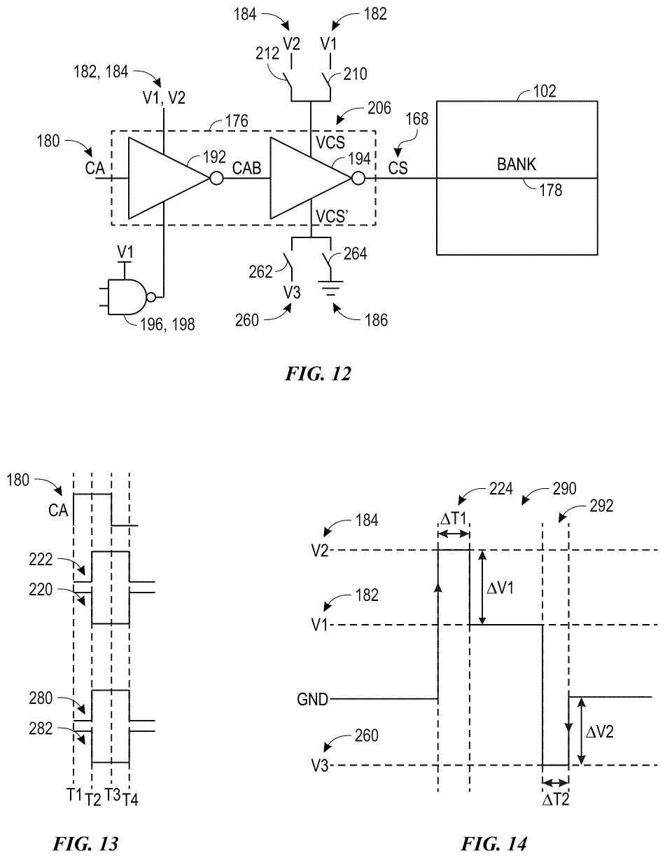

FIG. 12 is a column driver 176 of the second column driver group 166-2 described above, according to embodiments of the present disclosure. The column driver 176 may include the first inverter 192 and the second inverter 194 coupled to the memory bank 102 via the column select line 178. The negative supply voltage input of the first inverter 192 may be coupled to the first control logic 196 or the second control logic 198. In the depicted embodiment, the positive supply voltage input of the first inverter 192 may be coupled to the first supply voltage 182. Moreover, the supply voltage input of the first control logic 196 or the second control logic 198 may be coupled to the first supply voltage 182. In alternative or additional embodiments, the positive supply voltage input of the first inverter 192 and/or the supply voltage input of the first control logic 196 or the second control logic 198 may be coupled to the common supply voltage 206. For example, the second column driver group 166-2 may include the pull-up switch 214 described above with respect to FIG. 6.

The first switch 210 may couple the first supply voltage 182 to the positive supply voltage input of the second inverter 194. The second switch 212 may couple the second supply voltage 184 to the positive supply voltage input of the second inverter 194. The third switch 262 may couple the third supply voltage 260 to the negative supply voltage input of the second inverter 194. The fourth switch 264 may couple the first ground terminal 186 to the negative supply voltage input of the second inverter 194.

The first inverter 192 may generate a logic low bit based on inputting a logic high bit of the column address 180 selecting the column driver 176. The second inverter 194 may generate the column select signal 168 with a logic high bit. In some cases, the logic high bit of the column select signal 168 may have three voltage steps. The column select signal 168 may have a first voltage step followed by a second voltage step and a third voltage step. The first voltage step may have a voltage level based on the voltage level of the second supply voltage 184. The second voltage step may have a voltage level based on the voltage level of the first supply voltage 182. The third voltage step may have a voltage level based on the voltage level of the third supply voltage 260. The voltage level of the first voltage step may be higher than the voltage level of the second voltage step and the third voltage step. The voltage level of the third voltage step may be lower than the voltage level of the first voltage step and the second voltage step.

FIG. 13 is a timing diagram illustrating control signals 220, 222, 280, and 282 for providing the common supply voltage 206 with two voltage steps by the column driver 176 of FIG. 12 discussed above, according to embodiments of the present disclosure. The first switch 210, the second switch 212, the third switch 262, and the fourth switch 264 may receive the first control signal 220, the second control signal 222, the third control signal 280, and the fourth control signal 282 respectively. By way of example, the first switch 210 and the second switch 212 may each include pMOS transistors and the third switch 262 and the fourth switch 264 may each include nMOS transistors. The column driver 176 (e.g., the first inverter 192) may receive a rising edge of the logic high bit of the column address 180 at a time T1.

During a time period between times T1 and T2, the first control signal 220 and the fourth control signal 282 may have a high voltage level. The second control signal 222 and the third control signal 280 may have a low voltage level. The first switch 210 may be open, the second switch 212 may be closed, the third switch 262 may be open, and the fourth switch 264 may be closed. The second inverter 194 of the column drivers 176 may be coupled to the second supply voltage 184 and the first ground terminal 186 during the time period between the times T1 and T2. Moreover, the column driver 176 (e.g., the first inverter 192, the second inverter 194) may receive a portion of the logic high bit of the column address 180. Accordingly, the second inverter 194 may generate the column select signal 168 with the second voltage level based on the voltage level of the second supply voltage 184 during the time period between the times T1 and T2. For example, the second inverter 194 may couple the column select line 178 to the second supply voltage 184. The time period between the times T1 and T2 may correspond to the first voltage step of the three voltage steps.

During a time period between times T2 and T3, the first control signal 220 may have a low voltage level, the second control signal 222 may have a high voltage level, the third control signal 280 may have a high voltage level, and the fourth control signal 282 may have a low voltage level. As such, the first switch 210 may be closed, the second switch 212 may be open, the third switch 262 may be closed, and the fourth switch 264 may be open. The second inverter 194 of the column drivers 176 may be coupled to the first supply voltage 182 and the third supply voltage 260 during the time period between the times T2 and T3. Moreover, the column driver 176 (e.g., the first inverter 192, the second inverter 194) may receive a remaining portion of the logic high bit of the column address 180. Accordingly, the second inverter 194 may generate the column select signal 168 with the first voltage level based on the voltage level of the first supply voltage 182 during the time period between the times T2 and T3. For example, the second inverter 194 may couple the column select line 178 to the first supply voltage 182. The time period between the times T2 and T3 may correspond to the second voltage step of the three voltage steps.

During a time period between times T3 and T4, the first control signal 220 may have a low voltage level, the second control signal 222 may have a high voltage level, the third control signal 280 may have a high voltage level, and the fourth control signal 282 may have a low voltage level. As such, the first switch 210 may be closed, the second switch 212 may be open, the third switch 262 may be closed, and the fourth switch 264 may be open. The second inverter 194 of the column drivers 176 may be coupled to the first supply voltage 182 and the third supply voltage 260 during the time period between the times T2 and T3. Moreover, the column driver 176 (e.g., the first inverter 192, the second inverter 194) may receive a logic low voltage. Accordingly, the second inverter 194 may generate the column select signal 168 with the third voltage level based on the voltage level of the third supply voltage 260 during the time period between the times T3 and T4. For example, the second inverter 194 may couple the column select line 178 to the third supply voltage 260. The time period between the times T3 and T4 may correspond to the third voltage step of the three voltage steps.

It should be appreciated that time periods between T1 and T2, T2 and T3, and T3 and T4 may be different in different embodiments. Moreover, it should be appreciated that in alternative or additional embodiments, the first switch 210, the second switch 212, the third switch 262, and the fourth switch 264 of the column drivers 176 may each include a different switching circuit and/or transistor type. In such alternative or additional embodiments, the first control signal 220 and the second control signal 222 may be different based on the switching circuit and/or transistor type of the first switch 210 and the second switch 212. For example, the first control signal 220 and the second control signal 222 may each be inverted, delayed, or have different voltage levels and/or relative timings.

FIG. 14 is a graph illustrating the column select signal 168 generated by the selected column drivers 176 based on the three voltage steps discussed above with respect to FIGS. 11-13, according to embodiments of the present disclosure. In some embodiments, the column select signal 168 may initially have the voltage level (V2) of the second supply voltage 184 based on the second inverter 194 coupling to the second supply voltage 184. The common supply voltage 206 may subsequently have the voltage level (V1) of the first supply voltage 182 based on the second inverter 194 coupling to the first supply voltage 182. The common supply voltage 206 may subsequently have the voltage level (V3) of the third supply voltage 260 based on the second inverter 194 coupling to the third supply voltage 260. A first voltage level difference (ΔV1) between the voltage levels of the first supply voltage 182 and the second supply voltage 184 and a second voltage level difference (V2) between the ground voltage and the third supply voltage 260 may be adjusted by a second voltage adjustment circuit. The first time duration (ΔT1) for providing the voltage level of the second supply voltage and the second time duration (ΔT2) for providing the voltage level of the third supply voltage a may be adjusted by a delay circuit.

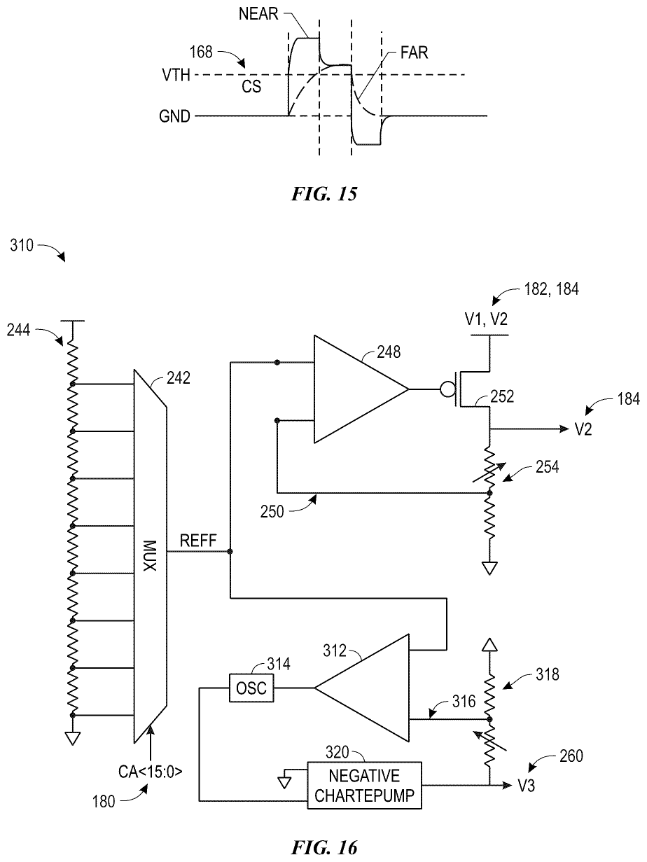

FIG. 15 is a graph illustrating voltage levels of the column select signal 168 generated by the column driver 176 (e.g., the second inverter 194) of FIG. 12 based on control signals 220, 222, 280, and 282 of FIG. 13 on the near and far sides of the column select line 178, according to embodiments of the present disclosure. In particular, the graph illustrates the three voltage steps of the column select signal 168 at or near the near side of the memory bank 102 and at or near the far side of the memory bank 102. The column select signal 168 may have a first voltage step 224 having a voltage level based on the voltage level of the second supply voltage 184. Subsequently, the column select signal 168 may have a second voltage step 290 having a voltage level based on the voltage level of the first supply voltage 182 followed by have a third voltage step 292 having a voltage level based on the voltage level of the third supply voltage 260.

The voltage level of the first voltage step 224 may be higher than the voltage level of the second voltage step 290 at or near the near side of the column select line 178. In some cases, a resistance and/or parasitic capacitance of the column select line 178 may reduce the voltage level of the column select signal 168 along the column select line 178. For example, the column select line 178 may have a higher resistance and/or parasitic capacitance for accessing target memory cells disposed near the far side of the memory bank 102 compared to accessing target memory cells disposed near the near side of the memory bank 102. As such, the voltage level of the first voltage step 224 may be reduced across the column select line 178. For example, the voltage level of the first voltage step 224 may be lower than the voltage level of the second voltage step 290 at or near the far side of the column select line 178.

The higher voltage level of the first voltage step 224 of the column select signal 168 may compensate for at least a portion of the resistance and/or parasitic capacitance for accessing the target memory cells disposed (or coupled to the column select line 178) near the far side of the memory bank 102. In some cases, the higher voltage level of the first voltage step 224 may increase a rising edge slope or time of the column select signal 168 at or near the far side of the memory bank 102. As such, the target memory cells coupled to the column select line 178 at or near the far side of the memory bank 102 may receive the column select signal 168 with a voltage level equal to or above the voltage threshold 228 for a time period equal to or above the desired time 230.

The voltage level of the third voltage step 292 may be lower than the voltage level of the first voltage step 224 and the second voltage step 290 at or near the near side of the column select line 178. As mentioned above, the resistance and/or parasitic capacitance of the column select line 178 may reduce the voltage level of the column select signal 168 along the column select line 178. As such, the voltage level of the third voltage step 292 may be reduced across the column select line 178.

The lower voltage level of the third voltage step 292 lower than the ground voltage may compensate for at least a portion of the resistance and/or parasitic capacitance for accessing the target memory cells disposed (or coupled to the column select line 178) near the far side of the memory bank 102. In some cases, the voltage level of the third voltage step 292 may increase a falling edge slope or time of the column select signal 168 at or near the far side of the memory bank 102. For example, the target memory cells coupled to the column select line 178 at or near the far side of the memory bank 102 may have reduced delay, residual voltage, and/or other undesired effects, based on the lower voltage level of the third voltage step 292 lower than the ground voltage.

In some embodiments, based on the three voltage steps of the logic high bit of the column select signal 168, the column select line 178 may be coupled to additional memory cells to increase a capacity of the memory bank 102. In specific embodiments, the second voltage adjustment circuit may adjust the voltage level of the second supply voltage 184 and/or the third supply voltage 260 based on a length of the column select line 178 or a disposition of the target memory cells along the column select line 178. In alternative or additional embodiments, the delay circuit may adjust the first time duration (ΔT1) for providing the voltage level of the second supply voltage 184, and/or the second time duration (ΔT2) for providing the voltage level of the third supply voltage 260, or both based on the length of the column select line 178 or the disposition of the target memory cells along the column select line 178. For example, the second voltage adjustment circuit and/or the delay circuit may adjust the voltage levels and/or the time durations based on the column address 180 of the target memory cell, segment addresses or section addresses of the target memory cell, among other possibilities.

FIG. 16 is a second voltage adjustment circuit 310 for adjusting a voltage level of the second supply voltage 184 and the third supply voltage 260 based on the column address 180, according to embodiments of the present disclosure. The second voltage adjustment circuit 310 may include the multiplexer 242, the resistor string 244, the first amplifier 248, the output switch 252, the first feedback resistors 254, a second amplifier 312, an oscillator 314, a negative charge pump, and second feedback resistors 318. The multiplexer 242 may receive the column address 180 associated with the second column driver group 166-2. As mentioned above, the input ports of the multiplexer 242 may each be coupled to a different resistor or between different resistors of the resistor string 244.

The resistor string 244 may be coupled to a voltage source on one side and to a ground terminal on the other side. The voltage source may include the first supply voltage 182 or any other viable voltage source of the memory device 100 of FIG. 1. As discussed above, the multiplexer 242 may generate the reference voltage 246 by selecting an input port based on the column address 180. In specific non-limiting cases, the column address 180 may indicate targeting a single memory cell or one or more memory cells of a single memory section or memory segment. In some embodiments, the multiplexer 242 may have a number of input ports corresponding to a number of the segments or sections of the memory bank 102 discussed above. For example, the multiplexer 242 may select an input port corresponding to a segment address or section address of the target memory cell based on the column address 180. Alternatively or additionally, the multiplexer 242 may receive the segment address or section address in lieu of or in addition to receiving the column address 180. In some embodiments, the second voltage adjustment circuit 310 (and/or the multiplexer 242) may include a lookup table to select the input port coupled to the resistor string 244 based on the segment address, the section address, and/or the column address 180.

The first amplifier 248 may generate the gate voltage of the output switch 252 based on receiving the reference voltage 246 and the first feedback signal 250. The output switch 252 may be coupled to a voltage source on one side and to a ground terminal via the first feedback resistors 254 on the other side. The first amplifier 248 may receive the first feedback signal 250 from the first feedback resistors 254. The voltage source may include the first supply voltage 182 or any other viable voltage source of the memory device 100 of FIG. 1. The output switch 252 may output the second supply voltage 184.

The second amplifier 312 may generate an input signal of the oscillator 314 based on receiving the reference voltage 246 and a second feedback signal 316. The second amplifier 312 may receive the second feedback signal 316 from the second feedback resistors 318 coupled to an output of the negative charge pump 320. The oscillator 314 may generate an oscillating signal based on receiving the input signal from the second amplifier 312. The negative charge pump 320 may input the oscillating signal. The negative charge pump 320 may output the third supply voltage 260 based on receiving the oscillating signal.

With the foregoing in mind, a voltage level of the reference voltage 246 may correspond to voltage levels of the second supply voltage 184 and the third supply voltage 260. For example, adjusting the voltage level of the reference voltage 246 may correspond to adjusting the voltage levels of the second supply voltage 184 and the third supply voltage 260. As mentioned above, the multiplexer 242 may output the reference voltage with a voltage level based on selecting a respective input port based on the column address, a segment address, or a section address of the target memory cell.

As such, the second voltage adjustment circuit 310 may provide the second supply voltage 184 and the third supply voltage 260 with voltage levels based on the column address 180 and/or the segment address or section address of the target memory cell. Accordingly, the second voltage adjustment circuit 310 may adjust the second supply voltage 184 and the first voltage level difference (ΔV1) between the voltage levels of the first supply voltage 182 and the second supply voltage 184. Moreover, the second voltage adjustment circuit 310 may adjust the third supply voltage 260 and a second voltage level difference (ΔV2) between voltage levels of the ground voltage and the third supply voltage 260. It should be appreciated that in different embodiments, the second voltage adjustment circuit 310 may include different circuitry to provide the second supply voltage 184 and/or the third supply voltage 260 based on the column address 180 and/or the segment address or section address of the target memory cell.

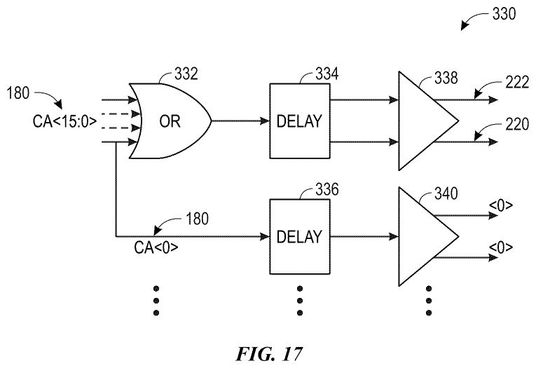

FIG. 17 is a delay circuit 330 for adjusting the first time duration (ΔT1) for providing the voltage level of the second supply voltage 184 and adjusting the second time duration (ΔT2) for providing the voltage level of the third supply voltage 260 based on the column address 180 of the target memory cell within a duration of a column select signal 168, according to embodiments of the present disclosure. The delay circuit 330 may include an OR logic circuit 332, a first delay component 334, a second delay component 336, a first buffer 338 (e.g., a first amplifier), and a second buffer 340 (e.g., a second amplifier).

The OR logic circuit 332 may receive the column address 180 of the target memory cells associated with the second column driver group 166-2 (e.g., CA <15:0>). The OR logic circuit 332 may output a logic high bit in response to any bits of the column address 180 having a logic high voltage. The OR logic circuit 332 may output the logic high bit to the first delay component 334. The first delay component 334 may delay the logic high bit. The first delay component 334 may output the delayed logic high bit to the first buffer 338. The first buffer 338 may output the first control signal 220 and the second control signal 222 in response to receiving the logic high bit. As discussed above, the first switch 210 and the second switch 212 of the second column driver group 166-2 may receive the first control signal 220 and the second control signal 222.

The second delay component 336 may receive a portion of the column address 180 (e.g., CA <0>, CA <1>, CA <2>, and so on) associated with memory cells coupled to a column select line 178 (e.g., a first column select line 178, a second column select line 178, and so on) of the second column driver group 166-2. The second delay component 336 may output a delayed logic high bit to the second buffer 340 in response to receiving a logic high bit. Alternatively, in some cases, the second delay component 336 may output a logic low bit to the second buffer 340 in response to receiving a logic low bit.

The second buffer 340 may output the third control signal 280 and the fourth control signal 282 in response to receiving the logic high bit. The third switch 262 and the fourth switch 264 associated with the column select line 178 of the portion of the column address 180 (e.g., CA <0>, CA <1>, CA <2>, and so on) may receive the first control signal 220 and the third control signal 280 and the fourth control signal 282. Accordingly, the delay circuit 330 may adjust the first time duration (ΔT1) for providing the voltage level of the second supply voltage 184, and/or the second time duration (ΔT2) for providing the voltage level of the third supply voltage 260.

In some embodiments, the first buffer 338 and the second buffer 340 may output the control signals 220, 222, 280, and 282 based on the timing diagram of FIG. 13. Although the first delay component 334, the second delay component 336, the first buffer 338 (e.g., a first amplifier), and the second buffer 340 are shown, it should be appreciated that the delay circuit 330 may include additional delay circuits and buffers, for example, for each of the remaining column select lines 178 coupled to the second column driver group 166-2 discussed above with respect to FIGS. 11 and 12. Moreover, it should be appreciated that in additional or different embodiments, the delay circuit 330 may include different circuitry to generate the control signals 220, 222, 280, and 282.

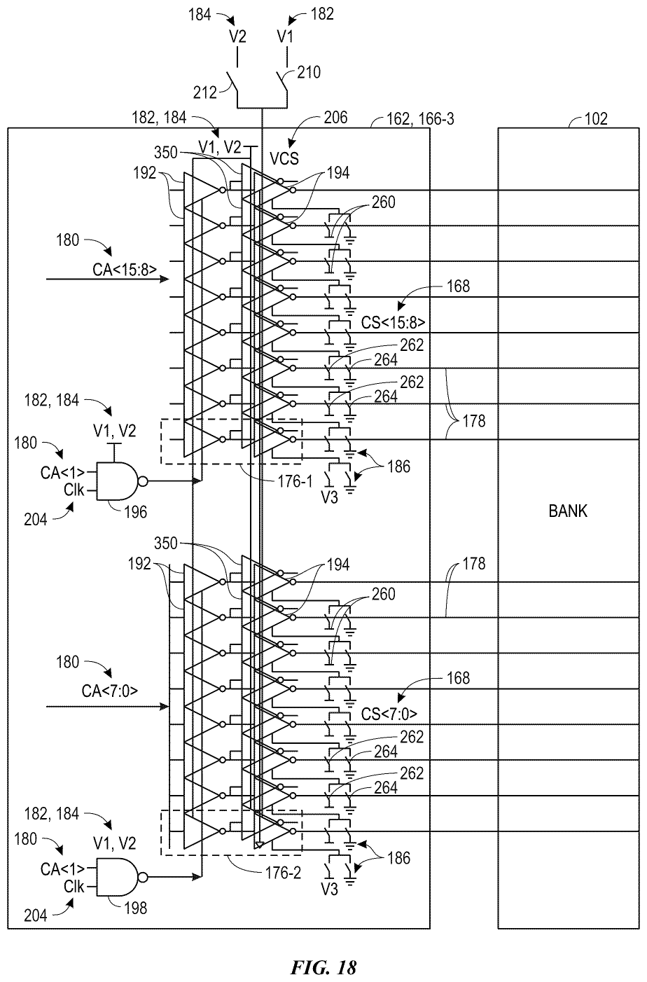

FIG. 18 is a block diagram of a third column driver group 166-3 of the column driver circuitry 162 having separate column select line drivers for targeting near and far memory cells of the memory bank 102, according to embodiments of the present disclosure. The third column driver group 166-3 may include the top column drivers 176-1, the bottom column drivers 176-2, the first control logic 196, and the second control logic 198. The column drivers 176 may each include the first inverter 192, the second inverter 194, and a third inverter 350.

Positive supply voltage inputs of the first inverters 192 and the third inverters 350 may be coupled to the first supply voltage 182. Negative supply voltage inputs of the first inverters 192 of the top column drivers 176-1 may be coupled to the first control logic 196. Negative supply voltage inputs of the first inverters 192 of the bottom column drivers 176-2 may be coupled to the second control logic 198. Supply voltage inputs of the first control logic 196 and the second control logic may couple to (or may be coupled to) the first supply voltage 182 or switch between coupling to the first supply voltage 182 and the second supply voltage 184. as discussed above with respect to FIGS. 5-7. Negative supply voltage inputs of the third inverters 350 of each column driver 176 may be coupled to output ports of the first inverters 192 of the respective column drivers 176.

Input ports of the second inverters 194 of each column driver 176 may be coupled to the negative supply voltage inputs of the third inverters 350 and the output ports of the first inverters 192 of the respective column drivers 176. The positive supply voltage inputs of the second inverters 194 may be coupled to the first supply voltage 182 and the second supply voltage 184 via the first switch 210 and the second switch 212 respectively. The negative supply voltage inputs of the second inverters 194 may be coupled to the third supply voltage 260 and the first ground terminal 186 via the third switch 262 and the fourth switch 264 respectively.

The third column driver group 166-3 may generate the column select signals 168 based on receiving the column address 180 (e.g., CA <15:0>) and the clock signal 204. The third inverter 350 may output the column select signals 168 when the column address 180 targets a near memory cell. The second inverter 194 may output the column select signals 168 when the column address 180 targets a far memory cell. In some cases, the third inverter 350 may provide the column select signals 168 based on a voltage level of the first supply voltage 182 coupled to the respective positive supply voltage input. Moreover, the second inverter 194 may provide the column select signals 168 based on the voltage levels of the first supply voltage 182, the second supply voltage 184, and/or the third supply voltage. For example, the second inverter 194 may provide the column select signals 168 based on operations of the first column driver group 166-1 described above with respect to FIGS. 4-10 or based on operations of the second column driver group 166-2 described above with respect to FIGS. 11-17.

As mentioned above, in some cases, the column select line 178 may have a higher resistance and/or parasitic capacitance for accessing target memory cells disposed near the far side of the memory bank 102 compared to accessing target memory cells disposed near the near side of the memory bank 102. Moreover, the resistance and/or parasitic capacitance of the column select line 178 may reduce the voltage level of the column select signal 168 along the column select line 178. As such, the third inverter 350 may provide the column select signals 168 to the near memory cells and the second inverter 194 may provide the column select signals 168 to the far memory cells.

In different embodiments, the far memory cells and the near memory cells may be associated with different column addresses 180, different groups of sections 172, and/or different groups of segments 170 of the memory bank 102. The different sections 172 and segments 170 of the memory bank 102 are described above with respect to FIG. 2. For example, the third inverter 350 may provide the column select signals 168 to the memory cells disposed with a first section 172 and/or a first segment 170 (e.g., or a first number of section 172 and/or segments 170) closest to the respective column driver 176. Moreover, the second inverter 194 may provide the column select signals 168 to the memory cells of the remainder of the sections 172 and/or segments 170.

In some embodiments, the memory controller 108 discussed above may enable and disable the second inverters 194 and the third inverters 350 of the third column driver group 166-3 based on the column address 180 of the target memory cells. Alternatively or additionally, the memory device 100 discussed above, or the third column driver group 166-3 may include additional circuitry. The additional circuitry may include a combination of logic circuits, among other possibilities. The additional circuitry may enable and disable the second inverters 194 and the third inverters 350 of the third column driver group 166-3 based on the column address 180 of the target memory cells. For example, the memory controller 108 and/or the additional circuitry, among other possibilities, may generate control signals enabling and disabling the switches 210, 212, 262, and 264. In some embodiments, the positive supply voltage inputs of the third inverters 350 may be coupled to the first supply voltage 182 via a fifth switch (not shown for simplicity). The fifth switch may receive the control signals to enable and disable the third inverter 350.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. A memory device comprising:
a plurality of memory cells coupled to a number of column select lines;
a column driver coupled to a column select line of the number of column select lines, wherein the column driver is configured to generate a single column select signal with at least two voltage levels to access a target memory cell of the plurality of memory cells coupled to the column select line.

2. The memory device of claim 1, wherein the column driver is configured to generate a first portion of the column select signal with a first voltage level of the at least two voltage levels, and generate a subsequent portion of the column select signal with a second voltage level of the at least two voltage levels lower than the first voltage level, wherein the first voltage level and the second voltage level are higher than a threshold voltage level associated with accessing the target memory cell.

3. The memory device of claim 2, wherein the column driver is coupled to a first supply voltage via a first switch and coupled to a second supply voltage via a second switch.

4. The memory device of claim 3, wherein the column driver is configured to couple to the first supply voltage via the first switch to generate the first portion of the column select signal with the first voltage level, and couple to the second supply voltage via the second switch to generate the subsequent portion of the column select signal with the second voltage level.

5. The memory device of claim 2, wherein the column driver is configured to generate a second subsequent portion of the column select signal with a third voltage level of the at least two voltage levels lower than a ground voltage level of the memory device.

6. The memory device of claim 1, comprising a ground terminal coupled to a far side of the column select line opposite to a side of the column select line coupled to the column driver via a ground switch.

7. The memory device of claim 6, wherein the memory device is configured to couple the far side of the column select line to the ground terminal based on a falling edge of the column select signal.

8. The memory device of claim 1. comprising a voltage adjustment circuit coupled to the column driver, wherein the voltage adjustment circuit is configured to adjust a voltage level of the at least two voltage levels based on a column address of the target memory cell.

9. A memory device comprising:
a plurality of memory cells coupled to a number of column select lines;
a first supply voltage;
a second supply voltage;
a column driver coupled to a column select line of the number of column select lines, wherein the column driver is configured to generate a single column select signal with at least two voltage levels based on coupling to the first supply voltage and the second supply voltage.

10. The memory device of claim 9, comprising a voltage adjustment circuit coupled to the column driver, wherein the voltage adjustment circuit is configured to adjust a voltage level difference between the first supply voltage and the second supply voltage based on a column address of a first target memory cell of the plurality of memory cells.

11. The memory device of claim 10, wherein the voltage adjustment circuit is configured to increase the voltage level difference to access a second target memory cell of the plurality of memory cells compared to the voltage level difference to access the first target memory cell, wherein the second target memory cell is disposed farther along the column select line with respect to the first target memory cell.

12. The memory device of claim 9, comprising a first switch coupled to the first supply voltage and the column driver, and a second switch coupled to the second supply voltage and the column driver.

13. The memory device of claim 12, wherein the column driver is configured to generate a first portion of the column select signal based on coupling to the first supply voltage via the first switch, and generate a subsequent portion of the column select signal based on coupling to the second supply voltage via the second switch.

14. The memory device of claim 9, wherein the at least two voltage levels are above a threshold voltage level associated with accessing a target memory cell of the plurality of memory cells.

15. A memory device comprising:
a plurality of memory cells coupled to a number of column select lines;
a first supply voltage;
a voltage adjustment circuit configured to provide a second supply voltage based on a column address of a first target memory cell of the plurality of memory cells; and
a column driver coupled to the first supply voltage, the second supply voltage, and a column select line of the number of column select lines, wherein the column driver is configured to generate a single column select signal with a first voltage level based on coupling to the first supply voltage and with a second voltage level based on coupling to the second supply voltage.

16. The memory device of claim 15, wherein the voltage adjustment circuit is configured to adjust a voltage level difference between the first supply voltage and the second supply voltage based on the column address of the first target memory cell.

17. The memory device of claim 16, wherein the voltage adjustment circuit is configured to increase the voltage level difference to access a second target memory cell of the plurality of memory cells compared to the voltage level difference to access the first target memory cell, wherein the second target memory cell is disposed farther along the column select line with respect to the first target memory cell.

18. The memory device of claim 15, wherein the column driver is configured to couple to the first supply voltage via a first switch to generate a first portion of the column select signal with the first voltage level, and couple to the second supply voltage via a second switch to generate the subsequent portion of the column select signal with the second voltage level.

19. The memory device of claim 15. comprising a third supply voltage, wherein the column driver is configured to generate a second subsequent portion of the column select signal with a third voltage level lower than a ground voltage level of the memory device based on coupling to the third supply voltage.

20. The memory device of claim 15, wherein the voltage adjustment circuit is coupled to the first supply voltage, wherein the voltage adjustment circuit is configured to generate the second supply voltage based on a voltage level of the first supply voltage.
